(19) United States
(12) Patent Application Publication
(10) Pub. No.: US 2026/0190832 A1
(43) Pub. Date: Jul. 2, 2026

(54) Display Device

(71) Applicant: LG Display Co., Ltd., Seoul (KR)

(72) Inventors: Sukhyun Kang, Goyang-si (KR); MinJoo Kim, Seoul (KR); Seonhee Lee, Seoul (KR); Dongil Chu, Gimpo-si (KR); Wonyeol Choi, Goyang-si (KR)

(21) Appl. No.: 19/394,627

(22) Filed: Nov. 19, 2025

(30) Foreign Application Priority Data
Dec. 31, 2024 (KR) 10-2024-0202970

(51) Int. Cl. H10K 59/80; H10K 59/35

(52) U.S. Cl. CPC H10K 59/8792; H10K 59/353

(57) ABSTRACT

A display device presented herein includes a substrate including a display area in which a plurality of sub-pixels is disposed and a non-display area surrounding the display area, a thin film transistor disposed on the substrate, an organic light emitting element disposed to correspond to each of the plurality of sub-pixels, a plurality of color filters disposed on the organic light emitting element to correspond to each of the plurality of sub-pixels, a black matrix dividing each of the plurality of color filters, and an overcoating layer covering the plurality of color filters and the black matrix. The overcoating layer includes a plurality of grooves overlapping the plurality of color filters and recessed by reducing at least a portion of a thickness of the overcoating layer in a downward direction toward the substrate from a top surface of the overcoating layer.

### CROSS-REFERENCE TO RELATED APPLICATION

The present application claims priority to Republic of Korea Patent Application No. 10-2024-0202970 filed on Dec. 31, 2024, which is incorporated herein by reference in its entirety.

### BACKGROUND

### Field

The present disclosure relates to a display device, and more particularly, to a display device with excellent luminous efficiency and improved rainbow mura phenomenon due to external light.

### Discussion of Related Art

Recently, as it enters the information age, the field of displays that visually express electrical information signals has been rapidly developed, and in response to this, various display devices with excellent performances such as thin-thickness, light weight, and low power consumption have been developed. Specific examples of such a display device include a liquid crystal display (LCD), a plasma display panel device (PDP), a field emission display device (FED), and an organic light emitting display device (OLED).

Among them, the organic light emitting display device includes an anode, a cathode, and an organic light emitting layer disposed therebetween. As the cathode is formed using a metal material having a high reflectance, external light is reflected by the metal material to deteriorate reflection visibility and a contrast ratio. Accordingly, in order to reduce reflection due to external light, a polarizing plate for absorbing external light is disposed under the cover member. The polarizing plate is a film having a predetermined level of light transmittance and absorbs external light and reflected light thereof to prevent a decrease in contrast ratio.

Meanwhile, in recent years, a flexible display device manufactured to display images even when it is bent or folded like paper is attracting attention as a next-generation display device. The flexible display device may be classified into an unbreakable display device having high durability, a bendable display device which may be bent without breaking, a rollable display device which may be rolled, and a foldable display device which may be folded. Such a flexible display device has advantages in space utilization, interior, and design, and may have various application fields.

In such a flexible display device, a structure in which a relatively thin coated polarization film is applied instead of a thick polarizer has been proposed. However, the coated polarizing film also has a problem in that the thickness is thick, and when the thickness is reduced, the function and display quality of the polarizing film are deteriorated.

Therefore, a Color Filter on Encapsulation layer (CoE) structure was proposed instead of the polarizer or the coated polarization film. The CoE structure of the related art is a structure in which a black matrix is disposed on an encapsulation layer so as to correspond to a non-emission area, and a color filter is disposed so as to correspond to the emission area. In the CoE structure, the thickness of the display device may be reduced, but the transmittance may be easily adjusted, such that external light and reflected light may be absorbed without degrading the luminous efficiency, thereby improving the display quality. However, when the CoE structure used in a flexible display device, there is a problem in that the color filter is peeled off to degrade the durability and the rainbow mura is generated by the color filter to degrade the display quality.

### SUMMARY

An object to be achieved by the present disclosure is to provide a display device with excellent luminous efficiency by improving a condensing effect in a display direction.

Another object to be achieved by the present disclosure is to provide a display device in which a luminance viewing angle is excellent and a rainbow mura phenomenon is suppressed while reducing reflectance.

Still another object to be achieved by the present disclosure is to provide a display device in which deterioration in display quality depending on a viewing angle in a bending area located outside the display device is suppressed.

Objects of the present disclosure are not limited to the above-mentioned objects, and other objects, which are not mentioned above, can be clearly understood by those skilled in the art from the following descriptions.

According to one or more embodiments of the present disclosure, a display device includes a substrate including a display area in which a plurality of sub-pixels is disposed and a non-display area surrounding the display area; a thin film transistor disposed on the substrate; an organic light emitting element disposed to correspond to each of the plurality of sub-pixels; a plurality of color filters disposed on the organic light emitting element to correspond to each of the plurality of sub-pixels; a black matrix dividing each of the plurality of color filters; and an overcoating layer covering the plurality of color filters and the black matrix, wherein the overcoating layer includes a plurality of grooves overlapping the plurality of color filters and recessed by reducing at least a portion of a thickness of the overcoating layer in a downward direction toward the substrate from a top surface of the overcoating layer.

Other detailed matters of the embodiments are included in the detailed description and the drawings.

According to the present disclosure, in the display device, light extraction efficiency from a light emitting element is improved to provide a display device with improved luminance and light emission efficiency.

Further, in the display device according to the present disclosure, it is possible to provide a display device in which the rainbow mura phenomenon is suppressed and reflectance is reduced even though a separate optical film is not provided on the color filter due to the novel structure of the color filter itself.

In addition, according to the present disclosure, it is possible to provide a display device in which a decrease in color viewing angle of the display device located in the bending area is suppressed.

Further, in the display device according to the present disclosure, a slim display device may be provided by omitting an optical film.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view of a foldable display device according to one or more embodiments of the present disclosure.

FIG. 2 is an enlarged plan view of one pixel in the display device according to one or more embodiments of the present disclosure.

FIG. 3 is a schematic cross-sectional view of II-II′ of FIG. 1.

FIGS. 4A to 4C are schematic cross-sectional views and plan views for explaining various structures of a groove according to one or more embodiments of the present disclosure.

FIG. 5A is an image for explaining a cross-sectional shape of the groove according to one or more embodiments of the present disclosure.

FIG. 5B is an image for describing a shape of a plane of the groove according to one or more embodiments of the present disclosure.

FIG. 6 is an enlarged plan view of one pixel in a display device according to one or more other embodiments of the present disclosure.

FIG. 7 is an enlarged plan view of one pixel in a display device according to one or more other embodiments of the present disclosure.

FIG. 8A is an enlarged plan view of one pixel for explaining the shape of a groove formed in a bending area in a display device according to one or more other embodiments of the present disclosure.

FIGS. 8B and 8C are an image for explaining the shape of the plane of the groove shown in FIG. 8A.

FIG. 9A is an enlarged plan view of one pixel for explaining the shape of a groove formed in a bending area in a display device according to one or more other embodiments of the present disclosure.

FIG. 9B is an image for explaining the shape of the plane of the groove shown in FIG. 9A.

FIGS. 10A and 10B are simulation images comparing the light emission efficiency of Comparative Example 1 and Embodiment 1 of the present disclosure.

FIGS. 11A and 11B are simulation images comparing reflectance of external light of Comparative Example 2 and Embodiment 2 of the present disclosure.

FIGS. 12A to 12D are simulation images evaluating reflectance according to an overlap rate of a groove according to one or more embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter embodiments of the present disclosure will be described in detail with reference to accompanying drawings.

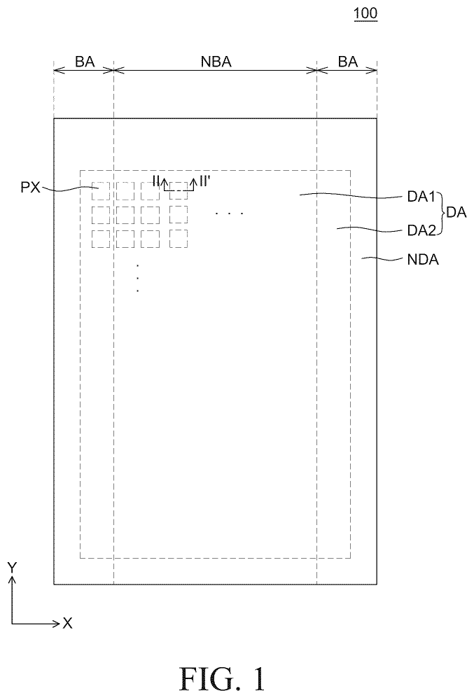

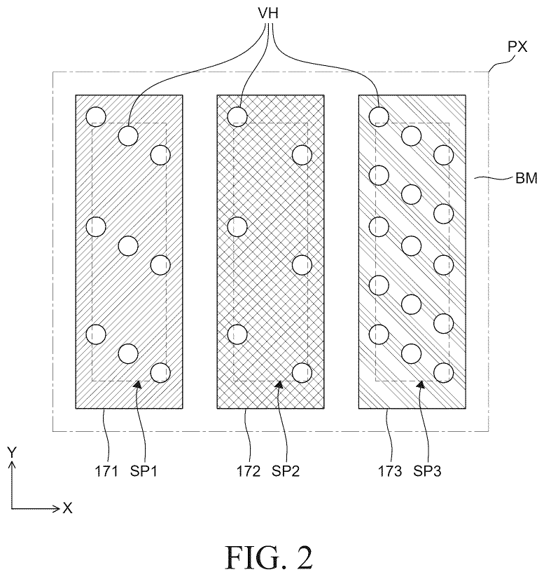

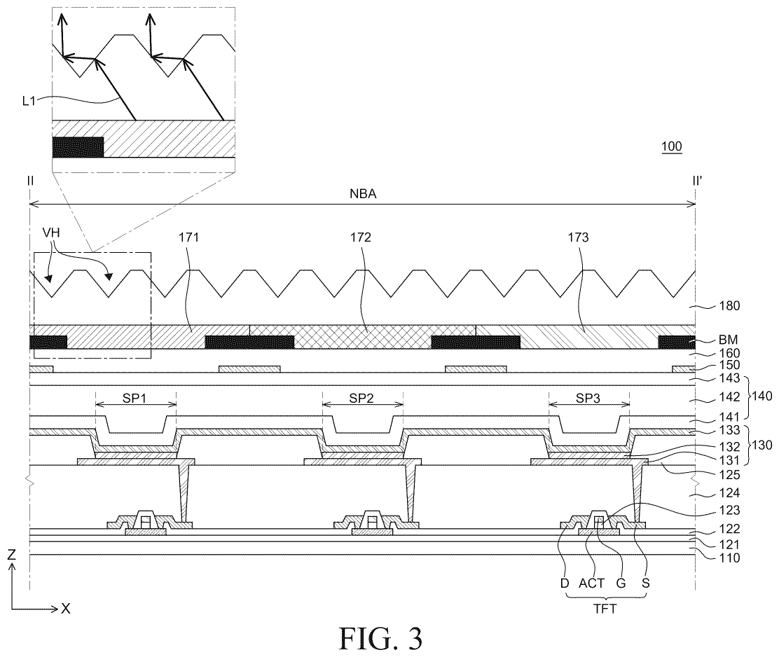

FIG. 1 is a schematic plan view of a foldable display device according to one or more embodiments of the present disclosure. FIG. 2 is an enlarged plan view of one pixel in the display device according to one or more of the present disclosure. FIG. 3 is a schematic cross-sectional view of II-II′ of FIG. 1.

A display device 100 according to one or more embodiments of the present disclosure includes a substrate 110, a thin film transistor TFT, an organic light emitting element 130, an encapsulation layer 140, a touch sensor layer 150, a black matrix BM, a color filter (for example, 171, 172, and 173), and an overcoating layer 180.

First, the display device 100 includes areas defined as a bending area BA and a non-bending area NBA. The bending area BA refers to an area that may be bent with respect to a virtual bending axis to have a curvature, and the non-bending area NBA refers to an area other than the bending area BA that is not bent and maintains a flat shape. Referring to FIG. 1, the bending area BA may be bent in an X-axis direction. The bending area BA may be located on both sides of the non-bending area NBA in the X-axis direction. FIG. 1 illustrates that the bending area BA is located on both sides of the non-bending area NBA, but may also be located between the non-bending areas NBA.

Meanwhile, the display device 100 includes areas defined as a display area DA and a non-display area NDA. The display area DA is an area in which a plurality of pixels PX are disposed and an image is substantially displayed. In the display area DA, a pixel PX including an emission area for displaying an image and a driving circuit for driving the pixel PX may be disposed. The non-display area NDA surrounds the display area DA. The non-display area NDA is an area where an image is not substantially displayed and various wiring lines, driving ICs, and printed circuit boards for driving pixels PX disposed in the display area DA and the driving circuits may be disposed in the non-display area NDA.

Meanwhile, the display area DA and the non-display area NDA may overlap at least one of the bending area BA and the non-bending area NBA. Accordingly, a partial area of the display device 100 may be a display area DA and a non-bending area NBA, and another partial area of the display device 100 may be a non-display area NDA and a bending area BA. Further, the display area DA of the display device 100 may be simultaneously located in the non-bending area NBA and the bending area BA. For example, referring to FIG. 1, the display area DA may include a first display area DA1 overlapping the non-bending area NBA and a second display area DA2 overlapping a part of the bending area BA.

Referring to FIG. 1, a plurality of pixels PX are arranged in a matrix shape. Referring to FIG. 2, each of the plurality of pixels PX includes a plurality of sub-pixels SP1, SP2, and SP3. The sub-pixels SP1, SP2, and SP3 are elements for displaying one color and include an emission area in which light is emitted and a non-emission area in which light is not emitted. In the present specification, only an emission area from which light is emitted is defined as a sub-pixel. For example, each of the plurality of sub-pixels may display any one of red, green, and blue colors, but is not limited thereto.

Referring to FIG. 2, one pixel PX may include a first sub-pixel SP1, a second sub-pixel SP2, and a third sub-pixel SP3. In the drawing, shapes and arrangements of the first sub-pixel SP1, the second sub-pixel SP2, and the third sub-pixel SP3 are illustrated as an example, but are not limited thereto. The shape of each of the sub-pixels SP1, SP2, and SP3 may be a circle or an oval, or may be a polygonal shape such as a triangle, a square, a pentagon, a hexagon, or the like, but is not particularly limited.

The first sub-pixel SP1, the second sub-pixel SP2, and the third sub-pixel SP3 may display different colors, or if necessary, some sub-pixels may display the same color. For example, the first sub-pixel SP1 may be a red sub-pixel, the second sub-pixel SP2 may be a green sub-pixel, and the third sub-pixel SP3 may be a blue sub-pixel, but not limited thereto. Even though in the drawing, the sizes of the sub pixels SP1, SP2, and SP3 are all illustrated as the same, the areas may be formed to be different for each color displayed by the sub pixels SP1, SP2, and SP3 in consideration of the luminance and the color temperature.

The substrate 110 is a base material for supporting various elements constituting the display device 100. For example, the substrate 110 may be a glass substrate or a plastic substrate. For example, the plastic substrate may be selected from polyimide, polyethersulfone, polyethylene terephthalate, and polycarbonate, but is not limited thereto. When a plastic substrate having flexibility is used, a support member such as a back plate may be disposed under the substrate 110. A plastic substrate having flexibility is relatively thin and less rigid than a glass substrate, so sagging may occur when various elements are disposed. The back plate supports the substrate 110 made of plastic so as not to sag and protects the display device 100 from moisture, heat, impact, and the like.

A substrate buffer layer 121 may be disposed on the substrate 110 to prevent permeation of oxygen or moisture. The substrate buffer layer 121 may be formed as a single layer, and may be formed in a multi-layered structure if necessary.

A thin film transistor TFT including a gate electrode G, an active layer ACT, a source electrode S, and a drain electrode D is disposed on the substrate buffer layer 121. The thin film transistor TFT is disposed in each of the first sub-pixel SP1, the second sub-pixel SP2, and the third sub-pixel SP3. In the drawing, for the convenience of description, only a driving thin film transistor among various thin film transistors that may be included in the display device 100 is illustrated.

The active layer ACT is disposed on the substrate buffer layer 121, and a gate insulating layer 123 for insulating the active layer ACT and the gate electrode G is disposed on the active layer ACT. Further, an interlayer insulating layer 122 for insulating the gate electrode G, the source electrode S, and the drain electrode D is disposed on the substrate buffer layer 121. The source electrode S and the drain electrode D respectively contacting the active layer ACT are formed on the interlayer insulating layer 122.

A planarization layer 124 may be disposed on the thin film transistor TFT. The planarization layer 124 planarizes an upper portion of the thin film transistor TFT. The planarization layer 124 may include a contact hole for electrically connecting the thin film transistor TFT and the anode 131 of the organic light emitting element 130. The organic light emitting element 130 is disposed on the planarization layer 124. The organic light emitting element 130 is disposed in each of the first sub-pixel SP1, the second sub-pixel SP2, and the third sub-pixel SP3. The organic light emitting element 130 disposed in each of the sub pixels SP1, SP2, and SP3 includes an anode 131, an organic emission layer 132, and a cathode 133.

The anode 131 is disposed on the planarization layer 124. The anode 131 may be patterned to correspond to each of the plurality of sub pixels SP1, SP2, and SP3. That is, the anode 131 may be formed to be separated for each of the first sub-pixel SP1, the second sub-pixel SP2, and the third sub-pixel SP3. The anode 131 is formed of a conductive material having a high work function as a component for supplying holes to the organic emission layer 132. The anode 131 may be a transparent conductive layer formed of transparent conductive oxide (TCO). For example, the anode 131 may be formed of one or more selected from transparent conductive oxides such as indium-tin-oxide (ITO), indium-zinc-oxide (IZO), indium-tin-zinc oxide (ITZO), tin oxide (SnO₂), zinc oxide (ZnO), indium-copper-oxide (ICO), and aluminum-doped zinc oxide (Al-doped ZnO, AZO), but is not limited thereto.

When the display device 100 is driven as a top emission type, the anode 131 may further include a reflective layer to reflect light emitted from the organic emission layer 132 toward the cathode 133.

The bank 125 is disposed on the anode 131 and the planarization layer 124. The bank 125 is disposed to cover an edge of the anode 131 of the organic light emitting element 130. That is, the bank 125 may cover an edge of the anode 131 to define a light emitting area. The bank 125 may divide the plurality of sub pixels SP1, SP2, and SP3. The bank 125 may be formed of an insulating material to insulate anodes 131 of adjacent sub pixels SP1, SP2, and SP3 from each other. Further, the bank 125 may be configured by a black bank having a high light absorption rate to prevent color mixture between adjacent sub pixels SP1, SP2, and SP3. The black bank may absorb external light introduced into the display device 100 through the color filters 171, 172, and 173 and the black matrix BM to be described later. Accordingly, it is possible to improve the reflective visibility by lowering the reflectance of external light. For example, the bank 125 may be formed of polyimide resin, acrylic resin, or benzocyclobutene resin, and may further include a black colorant or a dye of different colors in the organic material.

The cathode 133 is disposed on the anode 131. The cathode 133 may be formed of a metal material having a low work function to smoothly supply electrons to the organic emission layer 132. For example, the cathode 133 may be formed of a metal material selected from calcium (Ca), barium (Ba), aluminum (Al), silver (Ag), and an alloy including one or more of them, but is not limited thereto. The cathode 133 may be formed on the anode 131 as one layer. That is, the cathode 133 may be formed in the first sub-pixel SP1, the second sub-pixel SP2, and the third sub-pixel SP3 as a single layer. When the display device 100 is driven as a top emission type, the cathode 133 may be formed to have a very thin thickness to be substantially transparent.

The organic emission layer 132 is disposed between the anode 131 and the cathode 133. The organic emission layer 132 is a layer in which electrons and holes are combined to emit light. For example, the organic emission layer 132 may be separated for each of the plurality of sub pixels SP1, SP2, and SP3. In this case, the organic emission layer 132 is configured to emit light having the same color as that of a corresponding sub-pixel.

For example, the organic emission layer 132 corresponding to the first sub pixel SP1 may be a red organic emission layer, the organic emission layer 132 corresponding to the second sub pixel SP2 may be a green organic emission layer, and the organic emission layer 132 corresponding to the third sub pixel SP3 may be a blue organic emission layer. However, the present disclosure is not limited thereto. As another example, the organic emission layer 132 may be formed as a common layer without being separated for each of the plurality of sub pixels SP1, SP2, and SP3. In this case, the organic emission layer 132 is configured to emit white light and may emit light with a color corresponding to each of the sub pixels SP1, SP2, and SP3 through the color filters 171, 172, and 173.

The organic light emitting element 130 may further include a hole injection layer, a hole transport layer, an electron transport layer, an electron injection layer, and the like to improve luminous efficiency. For example, a hole injection layer and a hole transport layer may be disposed between the anode 131 and the organic emission layer 132, and an electron transport layer and an electron injection layer may be disposed between the organic emission layer 132 and the cathode 133. In addition, a hole blocking layer or an electron blocking layer may be disposed to further improve the recombination efficiency of holes and electrons in the organic emission layer 132.

The encapsulation layer 140 is disposed on the organic light emitting element 130. The encapsulation layer 140 may cover the organic light emitting element 130. The encapsulation layer 140 may protect the organic light emitting element 130 from external moisture, oxygen, impact, and the like. The encapsulation layer 140 may have a multi-layered structure in which an inorganic layer formed of an inorganic insulating material and an organic layer formed of an organic material are stacked. For example, the encapsulation layer 140 may be configured by at least one organic layer and at least two inorganic layers, and may have a multilayer structure in which inorganic layers and organic layers are alternately stacked, but is not limited thereto.

For example, the encapsulation layer 140 may have a triple-layered structure including a first inorganic layer 141, an organic layer 142, and a second inorganic layer 143. In this case, the first inorganic layer 141 and the second inorganic layer 143 may be independently formed of one or more selected from silicon nitride (SiNx), silicon oxide (SiOx), aluminum oxide (AlOx), and silicon oxynitride (SiON), but are not limited thereto. In addition, the organic layer 142 may be formed of one or more selected from epoxy resin, polyimide, polyethylene, and silicon oxycarbide (SiOC), but is not limited thereto.

For example, the encapsulation layer 140 may have a triple-layered structure including a first inorganic layer 141, an organic layer 142, and a second inorganic layer 143. In this case, the first inorganic layer 141 and the second inorganic layer 143 may be independently formed of one or more selected from silicon nitride (SiNx), silicon oxide (SiOx), aluminum oxide (AlOx), and silicon oxynitride (SiON), but are not limited thereto. Further, the organic layer 142 may be formed of one or more selected from epoxy resin, acrylic resin, silicone resin, polyimide, polyethylene, and silicon oxycarbide (SiOC), but is not limited thereto.

The touch sensor layer 150 is disposed on the encapsulation layer 140 to impart a touch sensing function to the display device 100. The touch sensor layer 150 is formed as a touch on encapsulation (ToE) structure in which the touch sensor layer 150 is formed on the encapsulation layer 140 without a separate substrate or an adhesive member in the display device 100 according to one or more embodiments of the present disclosure. In such a structure, when the distance between the organic light emitting element 130 and the touch sensor layer 150 is too short, parasitic capacitance is generated, thereby reducing touch sensitivity. Accordingly, the thickness of the encapsulation layer 140 may be appropriately adjusted to minimize or at least reduce the parasitic capacitance.

Although not illustrated in the drawings, an encap protection layer may be disposed on the encapsulation layer 140. In the process of forming the touch sensor layer 150 on the encapsulation layer 140, the encap protection layer may be disposed to protect the encapsulation layer 140, the organic light emitting element 130, and the like disposed therebelow. In addition, the encap protective layer improves adhesion between the touch electrode to be described later and the encapsulation layer 140. Further, the encap protection layer may protect a signal line or a pad unit disposed in the non-display area NDA from being damaged in the non-display area NDA. The encap protection layer may be formed of an inorganic insulating material, for example, one or more selected from silicon nitride (SiNx), silicon oxide (SiOx), aluminum oxide (AlOx), and silicon oxy nitride (SiON), but is not limited thereto.

The touch sensor layer 150 includes a plurality of touch electrodes. The plurality of touch electrodes are layers including electrodes for sensing a touch input, and may include a plurality of sensing electrodes and a plurality of driving electrodes, and may detect touch coordinates by sensing a change in capacitance between the plurality of sensing electrodes and the plurality of driving electrodes. For example, the sensing electrode and the driving electrode may be disposed on the same plane, and at least some of the plurality of touch electrodes may be electrically connected through a bridge electrode disposed on the other plane with an insulating layer therebetween. However, the present disclosure is not limited thereto, and the configuration of the touch sensor layer 150 may be variously changed as necessary.

Each of the plurality of touch electrodes may be disposed to correspond to a boundary of the sub pixels SP1, SP2, and SP3. That is, the touch electrode may be disposed on the encap protection layer so as to correspond between color filters 171, 172, and 173 adjacent to each other. In this case, the efficiency of light emitted from the organic light emitting element 130 may be maintained high without deteriorating, and the touch electrode is not visually recognized from the outside, so the display quality is excellent. The touch electrode may be formed of a transparent metal material such as indium-tin-oxide (ITO) or indium-zinc-oxide (IZO) capable of transmitting light, but is not limited thereto. However, the present disclosure is not limited thereto, and the configuration, material, and the like of the touch sensor layer 150 may be variously changed according to design.

The touch buffer layer 160 is disposed on the touch electrode. The touch buffer layer 160 is disposed to cover the touch electrode.

The touch buffer layer 160 protects the touch electrode from being damaged in a process of forming the black matrix BM and the color filters 171, 172, and 173 on the touch electrode. In addition, the touch buffer layer 160 may prevent penetration of moisture or oxygen from the outside and thus protect the touch electrode from being deteriorated.

The touch buffer layer 160 may have hydrophobicity. In this case, color filters 171, 172, and 173 including a plurality of lenses LS may be easily formed on the touch buffer layer 160. For example, the touch buffer layer 160 may be formed of one or more inorganic insulating materials selected from silicon nitride (SiNx), silicon oxide (SiOx), aluminum oxide (AlOx), and silicon oxy nitride (SiON), but is not limited thereto.

A plurality of color filters 171, 172, and 173 and a black matrix BM are disposed on the touch buffer layer 160. The plurality of color filters 171, 172, and 173 and the black matrix BM may serve as an anti-reflection layer which absorbs external light while maintaining high luminance of light emitted from the organic light emitting element 130 to minimize or at least reduce degradation of visibility and contrast ratio of the display device 100 due to external light.

The black matrix BM is disposed on the touch buffer layer 160 to overlap the bank 125. Accordingly, the black matrix BM is disposed to correspond to the touch electrode.

The black matrix BM is formed of a material having a high light absorption rate. Accordingly, the black matrix BM absorbs external light to improve the reflective visibility. The black matrix BM is formed to have a width greater than a width of each of the plurality of touch electrodes. Accordingly, the touch electrode is covered by the black matrix BM and is not visually recognized from the outside. Further, the touch electrode has a characteristic in which reflectance is higher than that of the black matrix BM due to the characteristics of the material itself, and as the black matrix BM is disposed on the touch electrode, the problem in that external light is reflected by the touch electrode to degrade the visibility may be reduced.

The black matrix BM may include a base resin and a black material. For example, the base resin may be one or more selected from cardo-based resin, epoxy-based resin, acrylate-based resin, siloxane-based resin, and polyimide, but is not limited thereto. For example, the black material may be a black pigment selected from a carbon-based pigment, a metal oxide-based pigment, and an organic pigment. For example, the carbon-based pigment may be carbon black. For example, the metal oxide-based pigment may be titanium black (TiNxOy), a Cu—Mn—Fe-based black pigment, or the like, but is not limited thereto. For example, the organic pigment may be selected from lactam black, perylene black, and aniline black, but is not limited thereto. Further, as the black material, an RGB black pigment including a red pigment, a blue pigment, and a green pigment may be used, but the present disclosure is not limited thereto.

The black matrix BM is disposed on the touch buffer layer 160 so as to be positioned between adjacent sub pixels SP1, SP2, and SP3. That is, the black matrix BM is disposed along a boundary of the adjacent sub pixels SP1, SP2, and SP3 and includes openings at a position corresponding to the sub pixels SP1, SP2, and SP3. Accordingly, light emitted from the organic light emitting element 130 may be emitted to the outside through the openings of the black matrix BM.

A distance between adjacent black matrices BM may be greater than a distance between adjacent banks 125. In this case, light emitted from the organic light emitting element 130 is emitted at a wide angle, thereby securing an advantage of excellent luminance viewing angle. The plurality of color filters 171, 172 and 173 are disposed on the touch buffer layer 160 so as to correspond to each of the plurality of sub pixels SP1, SP2, and SP3. The plurality of color filters 171, 172, and 173 absorb external light to minimize or at least reduce degradation of visibility and contrast ratio due to external light and improve color reproducibility. The plurality of color filters 171, 172, and 173 are disposed on the organic light emitting element 130 to improve luminous efficiency and omit a polarizer or a polarization film.

The color filters 171, 172, and 173 may include a first color filter 171 corresponding to the first sub pixel SP1, a second color filter 172 corresponding to the second sub pixel SP2, and a third color filter 173 corresponding to the third sub pixel SP3. The color filters 171, 172 and 173 may be configured to emit light of the same color as the corresponding sub pixels SP1, SP2, and SP3. When the first sub pixel SP1 is a red sub pixel, the first color filter 171 is a red color filter, when the second sub pixel SP2 is a green sub pixel, the second color filter 172 is a green color filter, and when the third sub pixel SP3 is a blue sub pixel, the third color filter 173 is a blue color filter. The first color filter 171 transmits red light. Here, the wavelength of red light may be about 620 nm to 750 nm. The second color filter 172 transmits green light. Here, the wavelength of green light may be about 495 nm to 570 nm. The third color filter 173 transmits blue light. Here, the wavelength of blue light may be about 440 nm to 495 nm.

Each of the color filters 171, 172 and 173 includes a transparent base resin and a color development material. For example, the transparent base resin may be one selected from polyacrylate, polymethyl methacrylate, polyimide, polyvinyl alcohol, polyethylene, polypropylene, polystyrene, polyethylene terephthalate, and the like, but not limited thereto.

The color development material absorbs light in a specific wavelength band and transmits light in the remaining wavelength bands. For example, the red color filter includes a red color development material that transmits light in a red wavelength band and absorbs light in green and blue wavelength bands. For example, the red color development material may be a perylene-based compound or a diketo-pyrrolopyrrole-based compound. For example, the green chromogenic material may be a phthalocyanine-based compound. For example, the blue chromogenic material may be a copper phthalocyanine-based compound or an anthraquinone-based compound. However, the color development material is not limited thereto, and any material that transmits light in red, blue, and green wavelength bands may be used without limitation.

As each color filter 171, 172, 173 is disposed so as to correspond to a color of each sub pixel SP1, SP2, SP3 corresponding thereto, internal light emitted from each of the first sub pixel SP1, the second sub pixel SP2, and the third sub pixel SP3 passes through the color filters 171, 172, and 173. For example, the red light emitted from the first sub pixel SP1 passes through the first color filter 171. On the other hand, when external light is incident, external light corresponding to the absorption wavelength of the color development material included in each of the color filters 171, 172, and 173 is absorbed by the color filters 171, 172, and 173. External light which is not absorbed by the color filters 171, 172, and 173 is reflected from the cathode 133 to pass through the color filters 171, 172, and 173 again. Reflected light corresponding to the absorption wavelength of the color development material included in each of the color filters 171, 172, and 173 is absorbed by the color filters 171, 172, and 173. Accordingly, the degradation of display quality due to external light may be minimized or at least reduced.

FIG. 3 exemplarily illustrates that the color filters 171, 172, and 173 are independently disposed so as to correspond to each of the plurality of sub-pixels SP1, SP2, and SP3, but are not limited thereto. A plurality of color filters 171, 172 and 173 may be formed as a single layer. For example, the plurality of color filters 171, 172, and 173 may be disposed as a single layer to cover upper portions of the touch buffer layer 160 and the black matrix BM. In this case, the plurality of color filters 171, 172, and 173 may include a base resin, a red color development material, a green color development material, and a blue color development material, but is not limited thereto. If necessary, some color development materials may be omitted, and other color development materials may be further included in addition to the red color development material, the green color development material, and the blue color development material.

The overcoating layer 180 is disposed on the color filters 171, 172 and 173 and the black matrix BM. The overcoating layer 180 planarizes the top surfaces of the color filters 171, 172 and 173 and the black matrix BM. Accordingly, the overcoating layer 180 may be formed to have a sufficient thickness to planarize the top surfaces of the color filters 171, 172, and 173 and the black matrix BM.

The overcoating layer 180 may be formed of a material having a refractive index larger than that of the color filters 171, 172, and 173. For example, the refractive index (200 nm to 1650 nm wavelength) of the color filters 171, 172, and 173 may be 1.42 to 1.83, and the refractive index (200 nm to 1650 nm wavelength) of the overcoating layer 180 may be 1.52 to 1.93. Within this range, the optical properties are excellent. In this case, a difference in refractive index between the color filters 171, 172, and 173 and the overcoating layer 180 may be adjusted to 0.05 to 0.10. In this case, the image quality of the display device is not distorted, and the rainbow mura phenomenon may be reduced. A large difference in refractive index may be more effective in solving the rainbow mura phenomenon, but distortion of image quality may occur, and if the difference in refractive index is too small, the rainbow mura phenomenon may occur.

For example, the overcoating layer 180 may be formed of a transparent resin such as acrylic resin, silicone resin, polyester resin, or epoxy resin, but is not limited thereto. The overcoating layer 180 may include a UV blocker or a UV absorber that blocks or absorbs light having a wavelength of 400 nm or less. Accordingly, deterioration of the display device 100 due to ultraviolet rays may be delayed. The UV blocker or UV absorber may be used without limitation as long as the UV blocker or UV absorber is a material used in the art.

The overcoating layer 180 includes a plurality of grooves VH. The groove VH has a concave shape by removing a portion of the overcoating layer 180. Specifically, the groove VH has a shape recessed downward from the upper surface of the overcoating layer 180 or a recessed shape. The groove VH may improve light extraction efficiency in an upward direction in the display area DA and suppress the rainbow mura.

When the plurality of grooves VH are provided on the upper surface of the overcoating layer 180, a difference in refractive index between the overcoating layer 180 and the groove VH occurs due to the groove VH. For example, the overcoating layer 180 may have a refractive index of 1.52 to 1.93. The groove VH is an air gap and may have a refractive index of 1.0±0.2. Referring to the enlarged area of FIG. 3, a part of the light emitted from the front surfaces of the color filters 171, 172, and 173 in the front direction is refracted at one boundary between the overcoating layer 180 and the groove VH. That is, at least a part of the light emitted from the organic light emitting element 130 is refracted in a direction parallel to the upper surface of the overcoating layer 180 due to the difference in refractive index between the groove VH and the overcoating layer 180. The refracted light is totally reflected due to the difference in refractive index between the groove VH and the overcoating layer 180 at the other boundary surface of the overcoating layer 180 and the groove VH to be emitted in the front direction. Accordingly, the light extraction efficiency of the light emitted from the color filters 171, 172, and 173 is improved, and thus the luminance of the display device may be improved.

The plurality of grooves VH are disposed to overlap the plurality of color filters 171, 172, and 173 and the black matrix BM. For example, the plurality of grooves VH may be disposed to overlap one color filter. Referring to FIG. 2, a plurality of grooves VH are disposed to overlap the first color filter 171. Further, the other plurality of grooves VH are disposed so as to overlap the second color filter 172 and the other plurality of grooves VH are disposed so as to overlap the third color filter 173.

The plurality of grooves VH may be arranged in a different number for each overlapping color filter. For example, when the first color filter 171 is a red color filter, the second color filter 172 is a green color filter, and the third color filter 173 is a blue color filter, the number of grooves VH overlapping the first sub pixel SP1 may be greater than the number of grooves VH overlapping the second green sub pixel, and less than the number of grooves VH overlapping the third sub pixel SP3. In general, since the luminous efficiency of the blue sub pixel is low, the groove VH may be provided the most in an area overlapping the third color filter 173 corresponding to the blue sub pixel. In addition, the smallest number of grooves VH may be provided in an area overlapping the second color filter 172 corresponding to a green sub-pixel having a relatively high luminous efficiency.

The plurality of grooves VH may be disposed at regular intervals, but is not limited thereto. In addition, the plurality of grooves VH may be partially disposed at regular intervals and patterns. Referring to FIG. 2, the plurality of grooves VH overlapping the first color filter corresponding to the first sub-pixel SP1 is disposed at regular intervals from each other. Likewise, a plurality of grooves VH overlapping a second color filter corresponding to the second sub pixel SP2 and a plurality of grooves VH overlapping a third color filter corresponding to the third sub pixel SP3 may be disposed at regular intervals. However, the number and arrangement structure of the plurality of grooves VH overlapping the first color filter may be different from the number and arrangement structure of the plurality of grooves VH overlapping the second color filter and the plurality of grooves VH overlapping the third color filter.

Referring to FIG. 2, the groove VH may have a circular shape in plan view, but is not limited thereto. For example, the groove VH may have an oval shape or a polygonal shape on a plane. Further, referring to FIG. 3, the groove VH may have a conical shape whose width is gradually narrowed in a downward direction on the cross-section. In this case, light emitted from the organic light emitting element 130 may be refracted at a boundary surface between the overcoating layer 180 and the groove VH which is diagonally inclined.

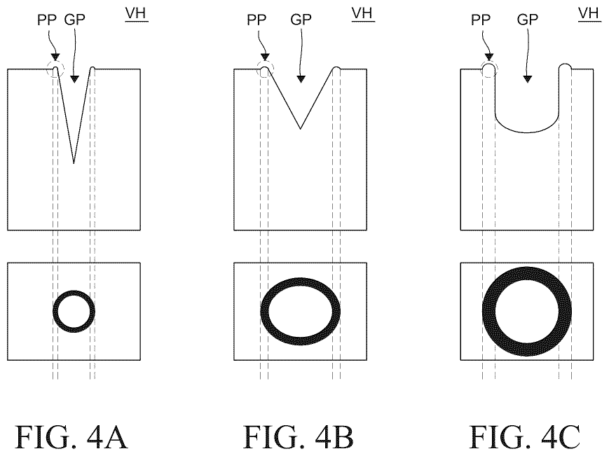

In order to describe various examples of the shape of the groove VH, the description will be made with reference to FIGS. 4A to 4C.

FIGS. 4A to 4C are schematic cross-sectional views and plan views for explaining various structures of the groove according to one or more embodiments of the present disclosure.

Referring to FIG. 4A, each groove VH may include a concave portion GP and a protruding portion PP. The concave portion GP has a shape recessed downward by removing a portion of the overcoating layer 180. The concave portion GP may have a shape in which a width is narrowed in a downward direction at least in part on a cross-section. For example, referring to FIG. 4A, the concave portion GP may have a conical shape whose width is gradually narrowed in a downward direction on the cross-section. Reflection and refraction of light emitted from the organic light emitting element 130 may occur at a boundary surface between the concave portion GP of the groove VH and the overcoating layer 180. Specifically, light emitted from the organic light emitting element 130 is refracted at a first boundary surface between the overcoating layer 180 and the groove VH which is diagonally inclined, and the refracted light is reflected upward from a second boundary surface located in a direction opposite to the first boundary surface. Accordingly, it is possible to improve the light extraction performance of light emitted from the organic light emitting device.

The depth of the concave portion GP may be 0.01 μm to 10 μm or 0.1 μm to 5 μm, but is not limited thereto. In addition, the upper portion of the concave portion GP may have a diameter of 5 μm to 50 μm. When the depth and size of the concave portion GP satisfy the above range, the light extraction efficiency of light emitted from the organic light emitting element disposed below the groove VH may be improved.

The protruding portion PP has a shape protruding upward from the upper surface of the overcoating layer 180. The protruding portion PP is formed on the upper surface of the overcoating layer 180 to surround the concave portion GP. The protruding portion PP may be formed to be connected to the concave portion GP. For example, as illustrated in FIG. 4A, the protruding portion PP has a shape extending from the side surface of the overcoating layer 180 in the concave portion GP and protruding toward the upper surface of the overcoating layer 180.

The protrusion PP scatters external light to reduce reflection of external light. In particular, the protruding portion PP formed in the plurality of grooves VH may suppress the rainbow mura phenomenon. In general, in order to ensure a luminance viewing angle while lowering the reflectance of external light, a pull-back structure in which the width of the color filter is formed to be wider than the width of the emission area defined by the corresponding bank is applied. However, when the pull-back structure is applied, the width of the black matrix BM is smaller than the width of the bank 125 so that the bank is exposed without being completely covered by the black matrix. Accordingly, there is a problem in that the rainbow mura phenomenon occurs due to the exposed bank 125, thereby deteriorating the display quality. The protruding portion PP is configured in plural to subdivide the spatial luminance distribution of external light to scatter external light incident into the display device to weaken the intensity of reinforcement/destructive interference, thereby suppressing the rainbow mura phenomenon.

The protrusion PP may have a triangular shape, a square pyramid shape, or a hemispherical shape in cross section, but is not limited thereto. The protrusion PP may have an irregular shape by its manufacturing method.

The height of the protrusion PP may be 0.01 μm to 1 μm or 0.05 μm to 0.5 μm. In addition, the width of the protruding portion PP may be 2 μm to 10 μm or 2 μm to 5 μm. When the height and width of the concave portion GP satisfy the range, external light may be scattered without lowering the light extraction efficiency and the rainbow mura phenomenon may be suppressed.

Referring to FIG. 4B, the concave portion GP of the groove VH shown in FIG. 4B may be shallower in depth and wider than the concave portion GP of the groove VH shown in FIG. 4A. In this case, the protruding portion PP of the groove VH shown in FIG. 4B may have a greater height and a greater width than the protruding portion PP of the groove VH shown in FIG. 4A.

Referring to FIG. 4C, the concave portion GP of the groove VH shown in FIG. 4C may have a different shape from the concave portion GP of the groove VH shown in FIG. 4B. Unlike the concave portion GP of the groove VH shown in FIG. 4B having a conical shape whose width is gradually narrowed in the downward direction on the cross-section, the concave portion GP of the groove VH shown in FIG. 4C may have the same width to a predetermined depth and then the width is narrowed to have an arc on the cross-section. In this case, the protruding portion PP of the groove VH shown in FIG. 4C may have a greater height and a greater width than the protruding portion PP of the groove VH shown in FIG. 4B.

As illustrated in FIGS. 4A to 4C, light extraction efficiency of light emitted from the light emitting element and reflectance of external light may be adjusted by varying shapes of the concave portion GP and the protruding portion PP.

The groove VH may be formed through a laser irradiation process. Specifically, the groove VH including the concave portion GP and the protruding portion PP may be formed by irradiating a laser onto the top surface of the overcoating layer 180. For example, when a laser having a specific energy is irradiated onto the top surface of the overcoating layer 180 for a predetermined time, a part of the overcoating layer 180 is removed to form the concave part GP. At the same time, a part of the top surface of the overcoating layer 180 adjacent to the concave part GP protrudes to form the protruding part PP surrounding the concave part GP. The depth and size of the concave portion GP and the height and width of the protruding portion PP may be adjusted according to the energy size and the laser wavelength during laser irradiation.

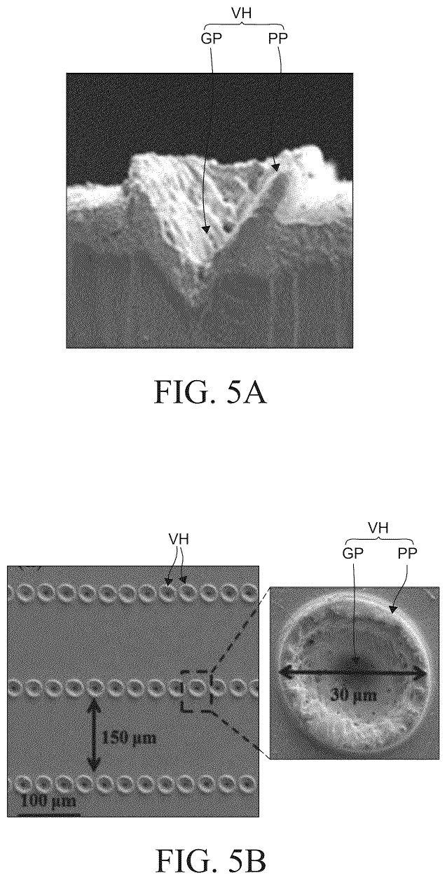

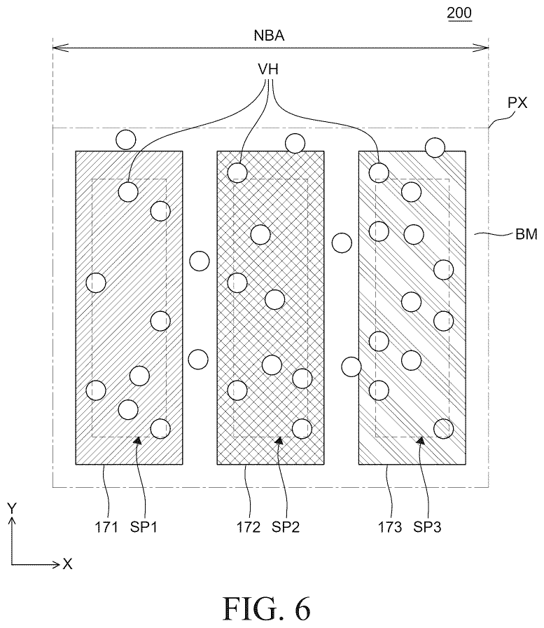

FIGS. 5A and 5B are images for explaining the shape of the groove VH according to one or more embodiments of the present disclosure. Specifically, FIG. 5A is an image for explaining a cross-sectional shape of the groove VH, and FIG. 5B is an image for explaining a planar shape of the groove VH.

Referring to FIG. 5A, it may be confirmed that the groove VH has a structure including a concave portion GP recessed from the top surface to the bottom surface of the overcoating layer 180 and a protruding portion PP protruding from the top surface of the overcoating layer 180 while surrounding the concave portion GP. In this case, the concave portion GP and the protruding portion PP may be connected to each other to form a V-shaped concave groove.

Referring to FIG. 5B, the grooves VH may be arranged side by side at regular intervals in the first direction, and may be disposed to be spaced apart at regular intervals in the second direction perpendicular to the first direction. For example, the grooves VH may be repeatedly disposed adjacent to each other to the extent that they are almost attached in the first direction. In addition, the grooves VH may be disposed to be spaced apart from each other in the second direction with a gap wider than a gap in the first direction, for example, with a gap of 150 μm.

In the display device according to one or more embodiments of the present disclosure, the groove VH including the concave portion GP and the protruding portion PP is formed in the overcoating layer 180. The concave portion GP has a shape whose width is narrowed from the top surface to the bottom surface of the overcoating layer 180, so that light extraction efficiency in the front direction may be improved by refracting and reflecting light emitted from a light emitting element located therebelow. Accordingly, the luminance and luminous efficiency of the display device 100 may be improved. Further, the top surface of the overcoating layer 180 has a non-flat surface through the protruding portion PP having a shape protruding upward from the top surface of the overcoating layer 180 while surrounding the concave portion GP. Accordingly, the path of the light incident from the outside is variously changed, the spatial luminance distribution of the external light is subdivided, and the constructive/destructive interference of the external light is weakened, thereby suppressing the rainbow mura phenomenon. In addition, it is possible to provide an effect of reducing reflectance by offsetting external light. According to one or more embodiments of the present disclosure, since a separate optical film is not required, the thickness of the display device may be implemented to be slim while improving the display quality, and the structure and process steps may be simplified.

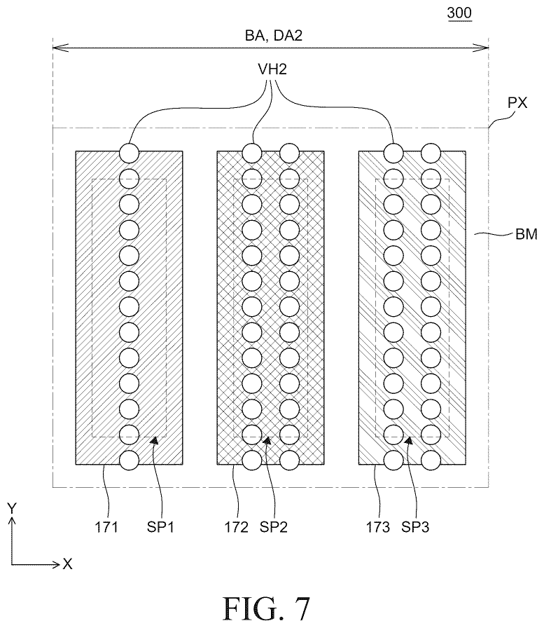

FIG. 6 is an enlarged plan view of one pixel in a display device according to one or more other embodiments of the present disclosure. A display device 200 illustrated in FIG. 6 has the substantially same configurations as the display device 100 illustrated in FIGS. 1 to 3, except that an arrangement of a plurality of grooves VH is different, so that a redundant description will be omitted.

Referring to FIG. 6, in a pixel disposed in the non-bending area NBA, the plurality of grooves VH may be randomly disposed. Specifically, the plurality of grooves VH may be disposed to be spaced apart from each other at irregular intervals over the entire display area DA regardless of the emission color of the sub-pixel. In this case, the plurality of grooves VH may be disposed so as to overlap the black matrix BM as well as the color filters 171, 172, and 173. Since the plurality of grooves VH are irregularly disposed, the protrusion portions PP provided in the plurality of grooves VH may also be irregularly disposed. The irregularly disposed protruding portion PP may irregularly scatter external light to further suppress the rainbow mura phenomenon.

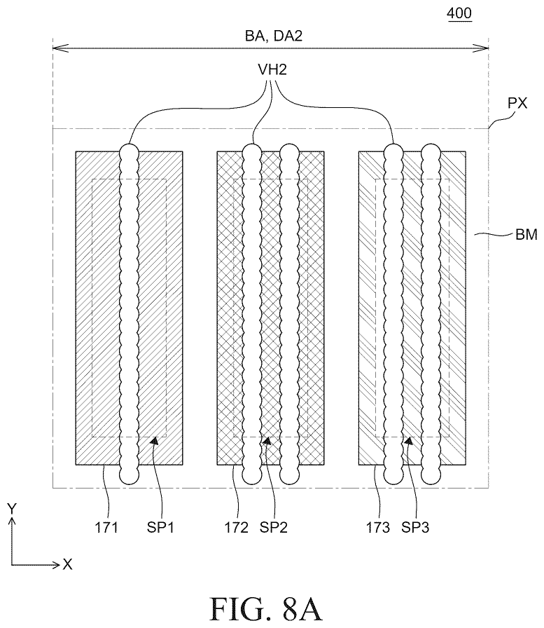

FIG. 7 is an enlarged plan view of one pixel in a display device according to one or more other embodiments of the present disclosure. A display device 300 illustrated in FIG. 7 has the substantially same configurations as the display device 100 illustrated in FIGS. 1 to 3, except that an arrangement of a plurality of grooves is different, so that a redundant description will be omitted.

In the display device illustrated in FIG. 7, the display area DA is disposed to overlap the non-bending area NBA and the bending area BA. For example, the display area DA includes a first display area DA1 overlapping the non-bending area NBA and a second display area DA2 overlapping the bending area BA. In this case, the plurality of grooves VH include a plurality of first grooves disposed in the first display area DA1 and a plurality of second grooves VH2 disposed in the second display area DA2. A plurality of first grooves disposed in the first display area DA1 overlapping the non-bending area NBA are substantially the same as the arrangement of the grooves VH shown in FIG. 2, and therefore, redundant descriptions thereof will be omitted.

The plurality of second grooves VH2 disposed in the second display area DA2 overlapping the bending area BA may be differently arranged from the plurality of first grooves VH disposed in the first display area DA1. Referring to FIG. 7, the plurality of second grooves VH2 are disposed to be constantly spaced apart at first intervals in the first direction (Y-axis direction) and spaced apart at second intervals in the second direction (X-axis direction) perpendicular to the first direction. Unlike the plurality of first grooves VH disposed in the non-bending area NBA, the plurality of second grooves VH2 disposed in the bending area BA are arranged in the second direction at regular intervals and is disposed in a larger number than the plurality of first grooves VH per unit area.

The light extraction efficiency of the second display area DA2 disposed in the bending area BA is reduced compared to the first display area DA1 disposed in the non-bending area NBA, and the color viewing angle in the curved surface is lowered. Therefore, the plurality of second grooves VH2 disposed in the second display area DA2 are disposed in a larger number than the plurality of first grooves VH disposed in the first display area DA1 per unit area to further improve the light extraction efficiency and improve the color viewing angle.

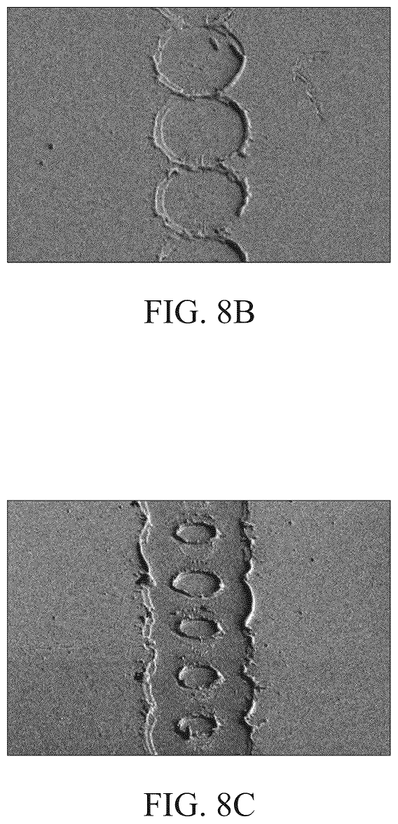

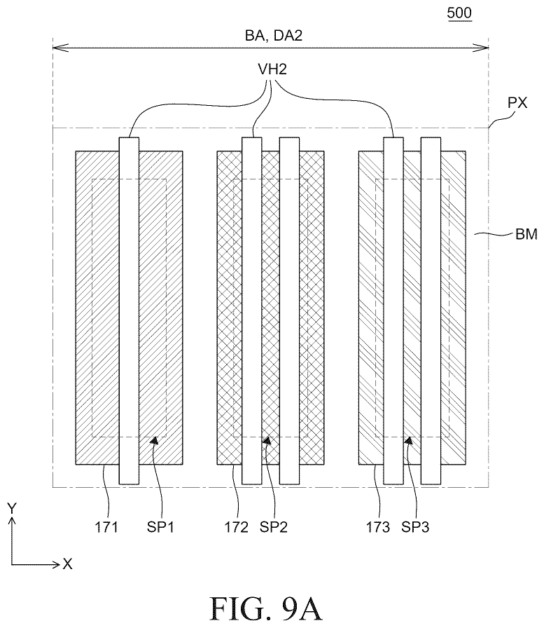

FIG. 8A is an enlarged plan view of one pixel for explaining the shape of a groove formed in a bending area in a display device according to one or more other embodiments of the present disclosure. FIGS. 8B and 8C are an image for explaining the shape of the plane of the groove shown in FIG. 8A. A display device 400 illustrated in FIG. 8A has the substantially same configurations as the display device 300 illustrated in FIG. 7 except that shapes of a plurality of second grooves VH2 are different, so that a redundant description will be omitted.

Referring to FIG. 8A, the plurality of second grooves VH2 are formed to at least partially overlap in the first direction (Y-axis direction), and is spaced apart from each other in the second direction (X-axis direction) perpendicular to the first direction. Accordingly, the plurality of second grooves VH2 have a shape elongated in the first direction.

When at least a part of the plurality of second grooves VH2 overlaps in the first direction (Y-axis direction), the overlapping area length of the plurality of second grooves VH2 may be 10% to 30% based on the width of one second groove VH2. The degree of reflection of external light may vary according to the degree of overlapping of the plurality of second grooves VH2. FIG. 8B is an image obtained by photographing a case in which a plurality of second grooves VH2 overlap by 10% based on the width of one second groove VH2. Further, FIG. 8C is an image obtained by photographing a case in which a plurality of second grooves VH2 overlap by 30% based on the width of one second groove VH2.

Meanwhile, referring to FIG. 8A, the second groove VH2 may have a shape of one row extending in the first direction. In this case, the side surface of the second groove VH2 may have a plurality of convexes repeated in the first direction and a plurality of concave between the plurality of convexes.

Each of the plurality of protrusions may have a curved shape having a curvature, and may have, for example, a circular or elliptical shape. The second groove VH2 of any one row extending in the first direction may have, for example, a shape in which at least one circle or oval is connected to each other in the first direction. In addition, each of at least one or more circles or ovals may partially overlap to extend in the first direction, but is not limited thereto. In this way, both side surfaces of each second groove VH2 may have a curved shape.

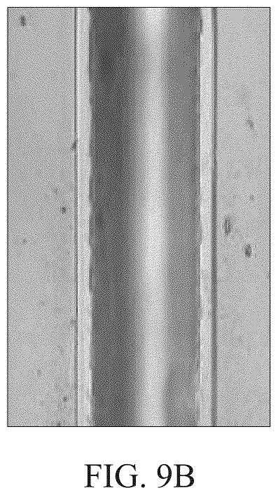

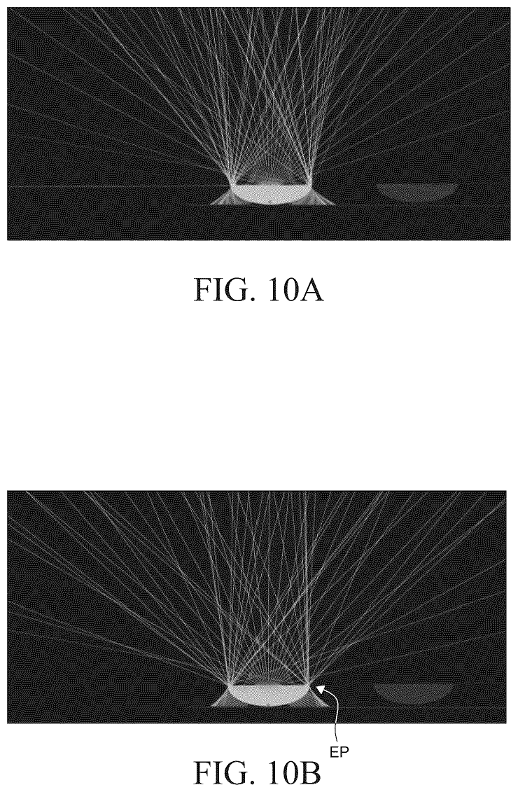

FIG. 9A is an enlarged plan view of one pixel for explaining the shape of the groove VH formed in the bending area BA in the display device according to one or more other embodiments of the present disclosure. FIG. 9B is an image for explaining a planar shape of the groove VH shown in FIG. 9A. A display device 500 illustrated in FIG. 9A has the substantially same configurations as the display device 400 illustrated in FIG. 8A except that shapes of a plurality of second grooves VH2 are different, so that a redundant description will be omitted.

Referring to FIG. 9A, each of the second grooves VH2 has a shape elongated in the first direction and is spaced apart from each other in the second direction (X-axis direction) perpendicular to the first direction. Unlike the second groove VH2 shown in FIG. 8A, which has a structure in which the flat circular grooves overlap each other, has a curved surface of the convex and the concave on the side surface, the second groove VH2 shown in FIG. 9A is formed in a linear shape on the flat side surface in the first direction. This is because the second groove VH2 is manufactured in a line process that constantly proceeds in one direction during laser irradiation.

Hereinafter, the effects of the present disclosure described above will be described in more detail with reference to embodiments. However, the following examples are for illustration of the present disclosure, and the scope of the present disclosure is not limited by the following examples.

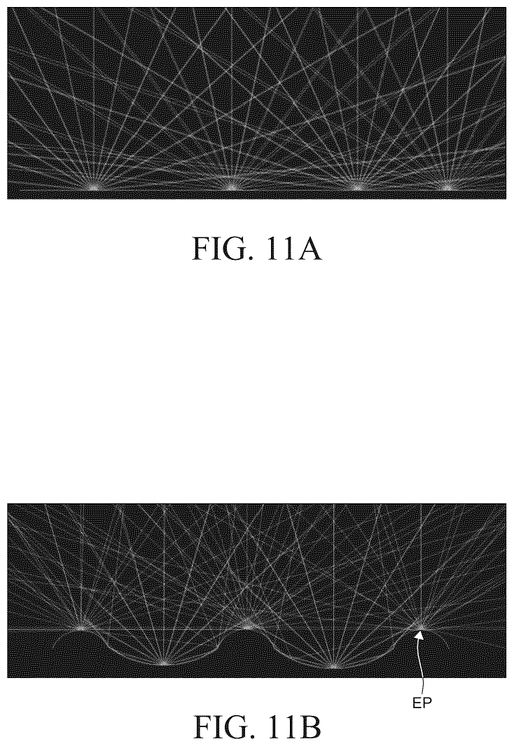

FIGS. 10A and 10B are simulation images comparing the light emission efficiency of Comparative Example 1 and Embodiment 1 of the present disclosure.

Comparative Example 1 according to FIG. 10A is an experimental example in which an overcoating layer is disposed on a color filter and a black matrix. Embodiment 1 according to FIG. 10B is an experimental embodiment in which one groove having a depth of 0.1 μm and a width of 20 μm is formed in the overcoating layer. Comparing FIGS. 10A and 10B, it may be seen that when the groove is formed in the overcoating layer, the straightness of light is improved by 8% or more by the protruding portion. Accordingly, it is possible to improve the luminous efficiency of the light emitting element.

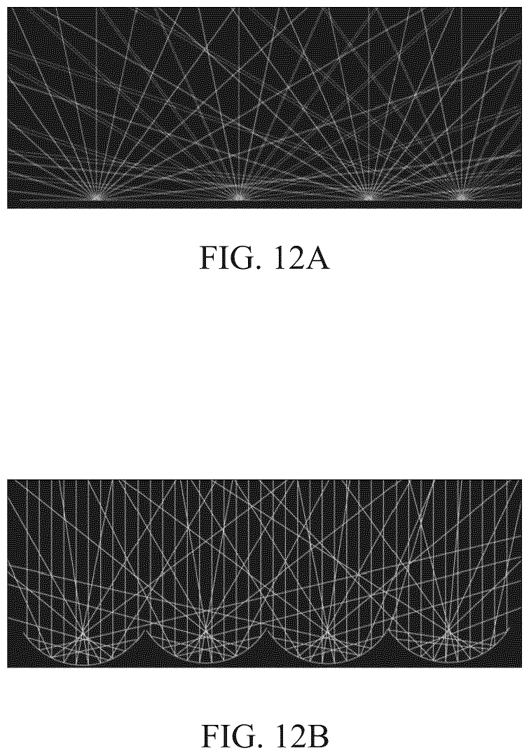

FIGS. 11A and 11B are simulation images comparing reflectance of external light of Comparative Example 2 and Embodiment 2 of the present disclosure.

Comparative Example 2 according to FIG. 11A is an experimental example in which an overcoating layer is disposed on a color filter and a black matrix. Embodiment 2 according to FIG. 11B illustrates an experimental embodiment in which two grooves having a depth of 0.1 μm and a width of 20 μm are formed in the overcoating layer. Comparing FIGS. 11A and 11B, it may be seen that when the groove is formed in the overcoating layer, the diffuse reflectance of external light increases by more than 23% due to the protruding portion. Through this, the rainbow mura phenomenon due to external light may be reduced and the reflective visibility may be improved.

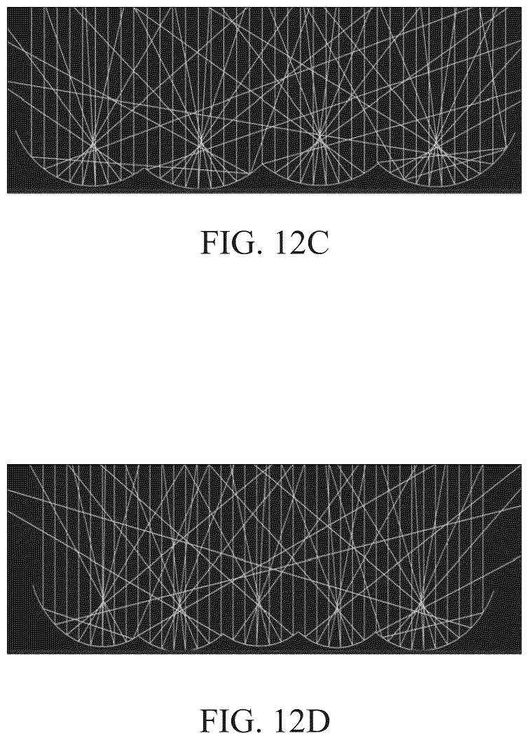

FIGS. 12A to 12D are simulation images evaluating reflectance according to an overlap rate of a groove according to one or more embodiments of the present disclosure.

First, FIG. 12A illustrates Comparative Example 3 representing an experimental example in which an overcoating layer is disposed on a color filter and a black matrix. FIG. 12B illustrates an experimental embodiment in which grooves having a depth of 0.1 μm and a width of 20 μm are formed in contact with each other without overlapping the overcoating layer. FIG. 12C illustrates an experimental embodiment in which a groove portion having a depth of 0.1 μm and a width of 20 μm is formed to overlap the overcoating layer with an overlap rate of 10%. FIG. 12D illustrates an experimental embodiment in which a groove portion having a depth of 0.1 μm and a width of 20 μm is formed to overlap the overcoating layer with an overlap rate of 30%.

Comparing FIGS. 12A and 12B, compared to the case where the groove is not formed, it may be confirmed that the diffuse reflectance increases by 14% when the groove is formed by combustion, so that the rainbow mura phenomenon caused by external light may be reduced. In addition, when FIGS. 12C and 12D are compared with FIG. 12A, it may be seen that when the grooves overlap, the diffuse reflectance increases by 18% and 16%, respectively. Accordingly, in the case of a structure in which the grooves are partially overlapped, it was confirmed that the diffuse reflection effect was slightly improved compared to the non-overlapping structure.

The embodiments of the present disclosure can also be described as follows:

According to one or more embodiments of the present disclosure, a display device includes a substrate including a display area in which a plurality of sub-pixels are disposed and a non-display area surrounding the display area; a thin film transistor disposed on the substrate; an organic light emitting element disposed to correspond to each of the plurality of sub-pixels; a plurality of color filters disposed on the organic light emitting element to correspond to each of the plurality of sub-pixels; a black matrix dividing each of the plurality of color filters; and an overcoating layer covering the plurality of color filters and the black matrix, wherein the overcoating layer includes a plurality of grooves overlapping the plurality of color filters and recessed by reducing at least a portion of a thickness of the overcoating layer in a downward direction toward the substrate from a top surface of the overcoating layer.

Each of the plurality of grooves may have a circular shape with an upper portion of the groove having a diameter of 5 μm to 50 μm parallel to the substrate.

Each of the plurality of grooves may include a concave portion recessed downward from the top surface of the overcoating layer and a protruding portion formed to surround the groove and protruding upward from the top surface of the overcoating layer.

According to one or more embodiments of the present disclosure, the depth of the concave portion recessed downward from the top surface of the overcoating layer may be 0.01 μm to 10 μm.

According to one or more embodiments of the present disclosure, the height of the protrusion protruding upward from the top surface of the overcoating layer may be 0.01 μm to 1 μm.

According to one or more embodiments of the present disclosure, the width of the protrusion may be 2 μm to 10 μm.

The plurality of sub-pixels may include a red sub-pixel, a green sub-pixel, and a blue sub-pixel, and the number of grooves overlapping the red sub-pixel may be greater than the number of grooves overlapping the green sub-pixel, and less than the number of grooves overlapping the blue sub-pixel.

The plurality of grooves may be spaced apart at a first interval in a first direction perpendicular to the downward direction and spaced apart at a second interval in a second direction perpendicular to the downward direction and the first direction, the second interval is greater than the first interval.

According to one or more embodiments of the present disclosure, the substrate may include a non-bending area and a bending area disposed outside the non-bending area, the display area may include a first display area overlapping the non-bending area and a second display area overlapping the bending area, and the plurality of grooves may include a plurality of first grooves disposed in the first display area and a plurality of second grooves disposed in the second display area.

According to one or more embodiments of the present disclosure, the plurality of first grooves may be disposed in a random arrangement.

According to one or more embodiments of the present disclosure, the number of the plurality of second grooves per unit area may be greater than the number of the plurality of first grooves.

According to one or more embodiments of the present disclosure, the plurality of second grooves may be formed to at least partially overlap in the first direction perpendicular to the downward direction and disposed to be spaced apart from each other in the second direction perpendicular to the downward direction and the first direction.

According to one or more embodiments of the present disclosure, the overlapping area length of the plurality of second grooves may be 10% to 30% based on the width of the second groove.

A side surface of each of the plurality of second grooves may have a plurality of convexes repeated in the first direction and a plurality of concaves between the plurality of convexes.

According to one or more embodiments of the present disclosure, the plurality of second grooves may have a shape elongated in the first direction and may be disposed to be spaced apart at second intervals in the second direction perpendicular to the first direction.

According to one or more embodiments of the present disclosure, there may be a difference in refractive index between the overcoating layer and each of the plurality of grooves, so that a part of the light emitted from the organic light emitting element is refracted at one boundary between the overcoating layer and the groove, and a part of the refracted light is totally reflected at the other boundary between the overcoating layer and the groove so as to be emitted in an upward direction opposite to the downward direction.

According to one or more embodiments of the present disclosure, the overcoating layer may have a refractive index of 1.52 to 1.93, and each of the plurality of grooves may be an air gap and have a refractive index of 1.0±0.2.

According to one or more embodiments of the present disclosure, each of the plurality of grooves may have a shape in which a width is narrowed in the downward direction at least in part on a cross-section

According to one or more embodiments of the present disclosure, each of the plurality of grooves may have a conical shape whose width is gradually narrowed in the downward direction on the cross-section.

According to one or more embodiments of the present disclosure, each of the plurality of grooves may have the same width to a predetermined depth and then the width may be narrowed in the downward direction to have an arc on the cross-section.

Although the embodiments of the present disclosure have been described in detail with reference to the accompanying drawings, the present disclosure is not limited thereto and may be embodied in various forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present invention. The protective scope of the present disclosure should be construed based on the following claims, and all the technical concepts in the equivalent scope thereof should be construed as falling within the scope of the present disclosure.

What is claimed is:

1. A display device, comprising:
a substrate including a display area in which a plurality of sub pixels is disposed and a non-display area surrounding the display area;
a thin film transistor disposed on the substrate;
an organic light emitting element disposed to correspond to each of the plurality of sub pixels;
a plurality of color filters disposed on the organic light emitting element to correspond to each of the plurality of sub pixels;
a black matrix dividing each of the plurality of color filters; and
an overcoating layer covering the plurality of color filters and the black matrix,
wherein the overcoating layer includes a plurality of grooves overlapping the plurality of color filters, and
wherein the plurality of grooves are recessed by reducing at least a portion of a thickness of the overcoating layer in a downward direction toward the substrate from a top surface of the overcoating layer.

2. The display device according to claim 1, wherein each of the plurality of grooves has a circular shape in which an upper portion of each of the plurality of grooves has a diameter of 5 μm to 50 μm on a plane parallel to the substrate.

3. The display device according to claim 1, wherein each of the plurality of grooves includes a concave portion recessed downward from the top surface of the overcoating layer and a protruding portion formed to surround the groove and protrude upward from the top surface of the overcoating layer.

4. The display device according to claim 3, wherein a depth of the concave portion recessed downward from the top surface of the overcoating layer is 0.01 μm to 10 μm.

5. The display device according to claim 3, wherein a height of the protruding portion protruding upward from the top surface of the overcoating layer is 0.01 μm to 1 μm.

6. The display device according to claim 3, wherein a width of the protruding portion is 2 μm to 10 μm.

7. The display device of claim 1, wherein the plurality of sub pixels includes a red sub-pixel, a green sub-pixel, and a blue sub-pixel,
wherein a number of grooves of the plurality of grooves overlapping the red sub-pixel is greater than a number of grooves of the plurality of grooves overlapping the green sub-pixel, and
wherein the number of grooves of the plurality of grooves overlapping the red sub-pixel is less than a number of grooves of the plurality of grooves overlapping the blue sub-pixel.

8. The display device according to claim 1, wherein the plurality of grooves are disposed to be spaced apart at a first interval in a first direction perpendicular to the downward direction and spaced apart at a second interval in a second direction perpendicular to the downward direction and the first direction, and wherein the second interval is greater than the first interval.

9. The display device according to claim 1, wherein the substrate includes a non-bending area and a bending area disposed outside the non-bending area,
wherein the display area includes a first display area overlapping the non-bending area and a second display area overlapping the bending area, and
wherein the plurality of grooves include a plurality of first grooves disposed in the first display area and a plurality of second grooves disposed in the second display area.

10. The display device according to claim 9, wherein the plurality of first grooves are disposed in a random arrangement.

11. The display device according to claim 9, wherein a number of the plurality of second grooves per unit area is greater than a number of the plurality of first grooves per unit area.

12. The display device according to claim 9, wherein the plurality of second grooves are formed to at least partially overlap in a first direction perpendicular to the downward direction and disposed to be spaced apart in a second direction perpendicular to the downward direction and the first direction.

13. The display device according to claim 12, wherein a length of an overlapping area of the plurality of second grooves is 10% to 30%, and wherein the length of the overlapping area is based on a width of a second groove the plurality of second grooves.

14. The display device according to claim 12, wherein side surfaces of the plurality of second grooves have a plurality of convexes repeated in the first direction and a plurality of concaves between the plurality of convexes.

15. The display device according to claim 12, wherein the plurality of second grooves have a shape elongated in the first direction, and wherein the plurality of second grooves are disposed to be spaced apart at second intervals in the second direction perpendicular to the first direction.

16. The display device according to claim 1, wherein a difference in refractive index between the overcoating layer and each of the plurality of grooves causes a part of light emitted from the organic light emitting element to be refracted at a first boundary between the overcoating layer and the groove, and further causes a part of the refracted light to be totally reflected at a second boundary between the overcoating layer and the groove so as to be emitted in an upward direction opposite to the downward direction.

17. The display device according to claim 16, wherein the overcoating layer has a refractive index of 1.52 to 1.93, and wherein each of the plurality of grooves is an air gap and has a refractive index of 1.0±0.2.

18. The display device according to claim 1, wherein each of the plurality of grooves has a shape in which a width is narrowed in the downward direction at least in part on a cross-section of the display device.

19. The display device according to claim 18, wherein:
each of the plurality of grooves has a conical shape whose width is gradually narrowed in the downward direction on the cross-section; or
each of the plurality of grooves has a same width to a predetermined depth and then a width of each of the plurality of grooves is narrowed in the downward direction to have an arc on the cross-section.
